(19) United States
(12) Patent Application Publication
(10) Pub. No.: US 2025/0151401 A1
(43) Pub. Date: May 8, 2025

(54) DISPLAY DEVICE AND METHOD OF MANUFACTURING DISPLAY DEVICE

(71) Applicant: SILICON DISPLAY TECHNOLOGY, Yongin-si (KR)

(72) Inventors: Jiwon PARK, Yongin-si (KR); Jae Ho SHIN, Yongin-si (KR); Jin Hyeong YU, Yongin-si (KR)

(21) Appl. No.: 18/740,706

(22) Filed: Jun. 12, 2024

(30) Foreign Application Priority Data
Nov. 2, 2023 (KR) 10-2023-0150325

(51) Int. Cl. H01L 27/12; H01L 25/16

(52) U.S. Cl. CPC H10D 86/60; H01L 25/167; H10D 86/021; H10D 86/471; H10D 86/423

(57) ABSTRACT

Disclosed is a display device including: a first TFT implemented as a Low-Temperature Polycrystalline Silicon (LTPS) TFT; a second TFT implemented as an oxide TFT stacked on the LTPS TFT; and a light emitting device formed next to a structure in which the first TFT and the second TFT are stacked, in which one electrode of the first TFT is connected to a gate of the second TFT, and one electrode of the second TFT is connected to the light emitting device.

### CROSS-REFERENCE TO RELATED APPLICATION

This application claims priority to and the benefit of Korean Patent Application No. 10-2023-0150325 filed in the Korean Intellectual Property Office on Nov. 2, 2023, the entire contents of which are incorporated herein by reference.

### BACKGROUND

### (a) Technical Field

The present disclosure relates to a TFT backplane structure used in manufacturing micro LED displays.

### (b) Description of the Related Art

FIG. 1 is a diagram illustrating an example of a connection of a driving circuit and a light emitting device using TFT in a subpixel. The TFT driving unit of the subpixel shown in FIG. 1 includes two TFTs, TFT A and TFT B, and one capacitor cap. The light emitting device may be implemented as a micro LED (μLED). As the pixel density of a display device including the micro LED is higher, the resolution may increase. Considering the market situation with increasing demands for higher resolution in display devices, the pixel density needs to be increased from the current level.

### SUMMARY

The present disclosure attempts to provide a display device capable of increasing pixel density.

The present disclosure attempts to reduce the area occupied by a TFT in a single subpixel by stacking LTPS TFTs and oxide TFTs to reduce a size of a subpixel and reduce a size of a pixel, thereby increasing pixel density of a display manufactured by using micro LEDs (uLEDs).

An exemplary embodiment of the present disclosure provides a display device including: a first TFT implemented as a Low-Temperature Polycrystalline Silicon (LTPS) TFT; a second TFT implemented as an oxide TFT stacked on the LTPS TFT; and a light emitting device formed next to a structure in which the first TFT and the second TFT are stacked. One electrode of the first TFT may be connected to a gate of the second TFT, and one electrode of the second TFT may be connected to the light emitting device.

The second TFT may include: a first active layer formed on a substrate; a first insulation layer formed on the first active layer; a first gate electrode formed on the first insulation layer; a second insulation layer formed on the first insulation layer and the first gate electrode; a first electrode layer connected to any one of a source region and a drain region of the first active layer through a first via electrode formed to penetrate the first insulation layer and the second insulation layer and formed on the second insulation layer; and a second electrode layer connected to the other of the source region and the drain region of the first active layer through a second via electrode formed to penetrate the first insulation layer and the second insulation layer and formed on the second insulation layer, and the first electrode layer is electrically connected to the light emitting device.

The first TFT may include: a third insulation layer formed on the first electrode layer and the second electrode layer; a second active layer formed on the third insulation layer; a third electrode layer formed on any one of a source region and a drain region of the second active layer; a fourth electrode layer formed on the other of the source region and the drain region of the second active layer; a fourth insulation layer formed on the third insulation layer, the third electrode layer, and the fourth electrode layer; and a second gate electrode formed on the fourth insulation layer to overlap the second active layer in a vertical direction, and the third electrode layer is electrically connected to the first gate electrode.

The display device may further include a fifth electrode layer connected to the first gate electrode through the first via electrode penetrating the second insulation layer and formed on the third insulation layer, in which the third electrode layer may be connected to the fifth electrode layer through a via electrode penetrating the third insulation layer.

The display device may further include: a fifth insulation layer formed on the fourth insulation layer and the second gate electrode; and a sixth electrode layer and a seventh electrode layer formed on the fourth insulation layer. The light emitting device may include an anode connected to the sixth electrode layer and a cathode connected to the seventh electrode layer.

The seventh electrode layer is connected to the first electrode layer through a via electrode penetrating the third to fifth insulation layers.

The light emitting device may be a micro LED.

Another exemplary embodiment of the present disclosure provides a method of manufacturing a display device, the method including: forming a first TFT, which is an LTPS TFT, on a substrate; forming a second TFT, which is an Oxide TFT, on the first TFT; and forming a light emitting device next to a structure in which the first TFT and the second TFT are stacked. One electrode of the second TFT may be connected to a gate of the first TFT, and one electrode of the first TFT may be connected to the light emitting device.

The present disclosure may provide a display device with improved pixel density and a method of manufacturing the display device.

### BRIEF DESCRIPTION OF THE DRAWINGS

FIG. 1 is a diagram illustrating an example of a connection of a driving circuit and an LED using TFT in a subpixel.

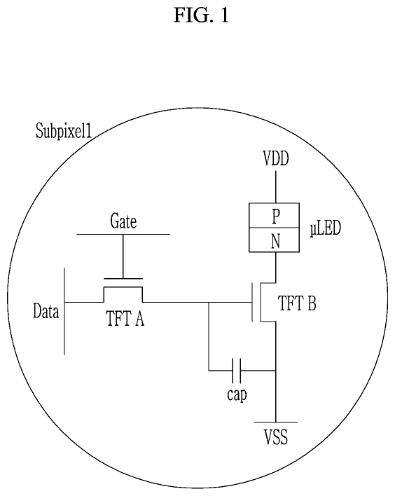

FIG. 2 is a diagram briefly and schematically illustrating the structure of the sub pixel.

FIG. 3 is a cross-sectional view of a stacked structure of the subpixel of FIG. 2.

FIG. 4 is a diagram briefly and schematically illustrating of a structure of an RGB pixel.

FIG. 5 is a diagram schematically illustrating the structure of the subpixel according to an exemplary embodiment.

FIG. 6 is a cross-sectional view of a stacked structure of a subpixel according to the exemplary embodiment.

FIG. 7 is a diagram schematically illustrating a structure of an RGB pixel according to an exemplary embodiment.

FIG. 8 is a diagram illustrating various TFT structures.

### DETAILED DESCRIPTION OF THE EXEMPLARY EMBODIMENTS

Some exemplary embodiments of the present disclosure include a low-temperature polycrystalline oxide (LTPO) TFT, and the LTPO TFT includes a low-temperature polycrystalline silicon (LTPS) TFT and an oxide TFT, and the LTPS TFT may operate as the p-type and the oxide TFTs may operate as the n-type. The LTPO TFT may operate as CMOS. The light emitting device of the present disclosure may be a micro-LED. In the following description, “LED” may refer to a micro LED.

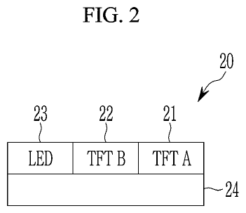

FIG. 2 is a diagram briefly and schematically illustrating a structure of a subpixel.

As shown in FIG. 2, a subpixel 20 may include a TFT A 21, a TFT B 22, an LED 23, and a substrate 24. The TFT A 21 and the TFT B 22 are LTPO TFTs and may be located on the substrate 24. The TFT A 21 may be implemented as an Oxide TFT, the TFT B 22 may be implemented as an LTPS TFT, and the TFT A 21 and the TFT B 22 may be horizontally separated without being stacked. The LED 23 may be located on the substrate and may be electrically connected to the TFT B 22.

FIG. 2 is intended to illustrate the horizontal positions of the configurations of the subpixel 20, and the actual vertical positions of the configurations may differ from FIG. 2. For example, the LED 23 may be formed at a higher position with respect to the TFT B 22, and there may also be a difference in vertical position between the TFT A 21 and the TFT B 22.

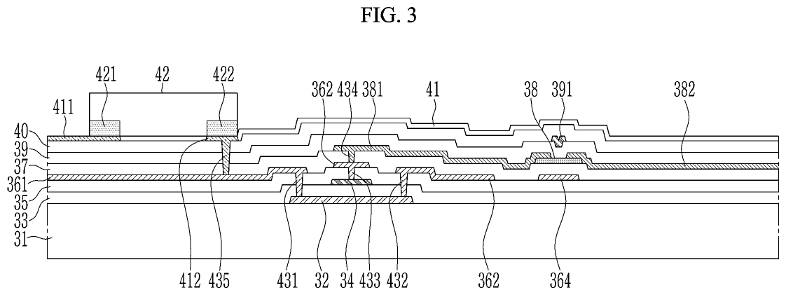

FIG. 3 is a cross-sectional view of a stacked structure of the subpixel of FIG. 2.

As shown in FIG. 3, an active layer 32 of the TFT B may be formed on the substrate 31, and an insulation layer 33 may be formed on the active layer 32. A gate electrode 34 may be formed on the insulation layer 33 to overlap the active region 32. An insulation layer 35 may be formed on the gate electrode 34, and electrode layers 361 to 363 may be formed on the insulation layer 35. The electrode layer 361 may be electrically connected to the source (or drain) region of the active layer 32 through a via electrode 431 formed to penetrate the insulation layers 33 and 35, the electrode layer 363 may be electrically connected to the source (or drain) region of the active layer 32 through a via electrode 432 formed to penetrate the insulation layers 33 and 35, and the electrode layer 362 may be connected to the gate electrode 34 through a via electrode 433 formed to penetrate the insulation layer 35. The gate electrode 364 may also be formed on the insulation layer 35 along with the electrode layers 361 to 363. An insulation layer 37 may be formed on the electrode layers 361 to 363, the gate electrode 364, and the insulation layer 35. The electrode layer 363 may be supplied with a voltage VSS to drive a subpixel circuit.

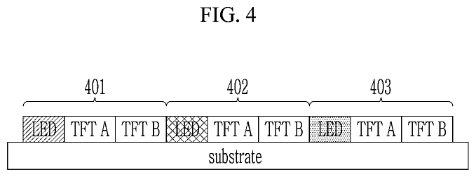

An active layer 38 of the TFT A is formed on the insulation layer 37, an electrode layer 381 is formed on the source region and the insulation layer 37 such that the electrode layer 381 is electrically connected to the source (or drain) region of the active layer 38, and an electrode layer 382 is formed on the drain region and the insulation layer 37 such that the electrode layer 382 is electrically connected to the drain (or source) region of the active layer 38. The electrode layer 382 may be provided with a corresponding data signal. The electrode layer 381 is electrically connected to the electrode layer 362 through a via electrode 434 formed to penetrate the insulation layer 37. An insulation layer 39 may be formed on the electrode layers 381 to 382, the active layer 38, and the insulation layer 37. The gate electrode 391 may be formed to overlap the active layer 364 in a vertical direction on the insulation layer 39. An insulation layer 40 may be formed on the insulation layer 39 and the gate electrode 391. In FIG. 4, the TFT A is implemented as a double gate structure including the gate electrode 364 and the gate electrode 391, but the present disclosure is not limited thereto. The gate electrode 364 and the gate electrode 391 may be supplied with corresponding gate signals.

An electrode layer 411 is formed on the insulation layer 40, and an electrode layer 412 is connected to the electrode 361 through a via electrode 435 formed to penetrate the insulation layers 37, 39, and 40 and is formed on the insulation layer 40. An insulation layer 41 may be formed on the electrode layers 411 and 412 and the insulation layer 40. The electrode layer 411 may be supplied with a voltage VDD to drive the subpixel circuit.

The LED light emitting layer 42 is formed on the insulation layer 41 and the electrode layers 411 and 412, and an anode region 421 of the LED light emitting layer 42 is formed on the electrode 411 to overlap a portion of the electrode 411, and a cathode region 422 is formed on the electrode 412 to overlap the electrode 412.

FIG. 4 is a diagram briefly and schematically illustrating a structure of an RGB pixel.

As shown in FIG. 4, each of the subpixels 401, 402, and 403 of R, G, and B are horizontally positioned, so that an area occupied by the TFT may be large. In this case, there may be a limitation in increasing the pixel per inch (ppi) by reducing the size of the pixels.

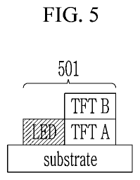

FIG. 5 is a diagram schematically illustrating a structure of the subpixel according to the exemplary embodiment.

In FIG. 5, in a red (R) subpixel 501, the TFT A and the TFT B are positioned in a vertical direction such that the area occupied by the TFTs may be reduced compared to FIG. 4. In other words, the ppi may be improved.

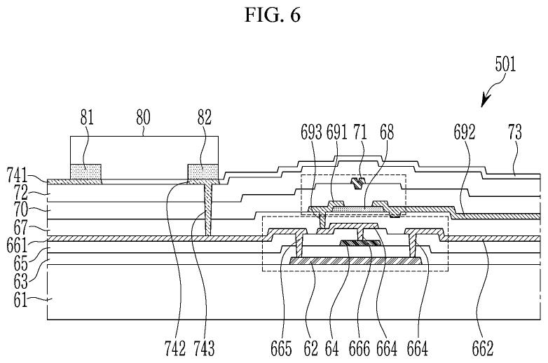

FIG. 6 is a cross-sectional view of a stacked structure of the subpixel according to the exemplary embodiment.

A cross-section of the R subpixel 501 shown in FIG. 5 is shown in FIG. 6.

As shown in FIG. 6, an subpixel according to an exemplary embodiment may be implemented by first forming a TFT B 520, which is an LTPS TFT, on a substrate 61, forming a TFT A 510, which is an Oxide TFT, on the TFT B 520, and then forming an LED 80 that is a light emitting device next to the structure in which the TFT B 520 and the TFT A 510 are stacked. As described above, the TFT A 510 and the TFT B 520 is stacked, so that the area occupied by the TFTs in one subpixel may be reduced. Then, the size of the subpixel is reduced, and the size of the pixel is reduced, which increase the pixel density of the display manufactured by using uLEDs. In other words, the pixel density can be improved by reducing the area occupied by the TFTs in the active panel RGB module.

An active layer 62 of the TFT B may be formed on the substrate 61, and an insulation layer 63 may be formed on the active layer 62. A gate electrode 64 may be formed on the insulation layer 63 to overlap the active region 62. An insulation layer 65 may be formed on the gate electrode 64, and electrode layers 661 to 663 may be formed on the insulation layer 65. An electrode layer 661 may be electrically connected to the source (or drain) region of the active layer 62 through a via electrode 665 formed to penetrate the insulation layers 63 and 65, an electrode layer 662 may be electrically connected to the drain (or source) region of the active layer 62 through a via electrode 664 formed to penetrate the insulation layers 63 and 65, and an electrode layer 663 may be electrically connected to the gate electrode 64 through a via electrode 666 formed to penetrate the insulation layer 65. An insulation layer 67 may be formed on the electrode layers 661 to 663 and the insulation layer 65. The electrode layer 662 may be supplied with a voltage VSS to drive the subpixel circuit.

An active layer 68 is formed on the insulation layer 67, an electrode layer 691 is formed on the source region and the insulation layer 67 such that the electrode layer 691 is electrically connected to the source (or drain) region of the active layer 68, and an electrode layer 692 is formed on the drain region and the insulation layer 67 such that the electrode layer 692 is electrically connected to the drain (or source) region of the active layer 68. The electrode layer 692 may be provided with a corresponding data signal. The electrode layer 691 is electrically connected to the electrode layer 663 through a via electrode 693 formed to penetrate the insulation layer 67. An insulation layer 70 may be formed on the electrode layers 691 and 692, the active layer 68, and the insulation layer 67. The gate electrode 71 may be formed to overlap the active layer 68 in a vertical direction on the insulation layer 70. An insulation layer 72 may be formed on the insulation layer 70 and the gate electrode 68. The gate electrode 71 may be supplied with a corresponding gate signal.

An electrode layer 741 is formed on the insulation layer 72, and an electrode layer 742 is connected to the electrode 661 through a via electrode 743 formed to penetrate the insulation layers 67, 70, and 72 and is formed on the insulation layer 72. An insulation layer 73 may be formed on the electrode layers 741 and 742 and the insulation layer 72. The electrode layer 741 may be supplied with a voltage VDD to drive the pixel circuit.

The LED light emitting layer 82 is formed on the insulation layer 73 and the electrode layers 741 and 742, and an anode region 81 of the LED light emitting layer 82 is formed on the electrode 741 to overlap a portion of the electrode 741, and a cathode region 82 is formed on the electrode 742 to overlap the electrode 742.

As shown in FIG. 6, the two TFT structures are LTPO (LTPS+Oxide) structures. The TFT A 510 is formed of an oxide and the TFT B 520 is formed of LTPS. The advantage that the TFT A 510 is stacked on the TFT B 520 to reduce the area occupied by the TFT may be provided while maintaining the advantages of the LTPO TFTs, that is, the poly-Si TFT B 520 operates as the p-type and the oxide TFT A 510 operates as the n-type.

The exemplary embodiments of FIGS. 5 and 6 may be applied to the subpixels of other colors.

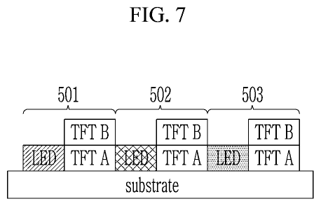

FIG. 7 is a diagram schematically illustrating a structure of an RGB pixel according to an exemplary embodiment.

The green subpixel 502 and the blue subpixel 503 formed according to the subpixel structure shown in FIG. 5 are continuously arranged in a horizontal direction in a row on the red subpixel 501. The description of the stacked structure of the green subpixel 502 and the blue subpixel 503 is the same as the detailed description of FIG. 5 and FIG. 6. The structure of the subpixels according to FIG. 7 may have a reduced area occupied by the TFT in the horizontal direction due to the vertically stacked TFT structure shown in FIG. 7 compared to the structure of the subpixels shown in FIG. 4. The size of the subpixel may be reduced, and thus the size occupied by the pixels may be reduced.

The pixel structure shown in the present disclosure is an example to describe the disclosure, and the height and shape of each layer in the disclosure is not limited to the drawings.

The exemplary embodiment described above is an example of an RGB LED structure, and the TFTs and LEDs may be arranged in a different order and shape from those shown in this disclosure and drawings. Although the present disclosure uses an RGB structure as an example, the present disclosure may also be applied to pixel structures that include additional subpixels, such as RGBW, for improved color sensitivity. The pixels may be arranged in various combination methods, such as GB and GR structures, in addition to RGB arrangements. A substrate material is not limited to glass, but may include various materials, such as silicon or PI. In one exemplary embodiment, some or all of the portions indicated by LEDs may be implemented with various light emitting devices, such as OLEDs, quantum dots, and mini LEDs, in addition to uLEDs. Accordingly, the present disclosure is applicable to various light emitting methods.

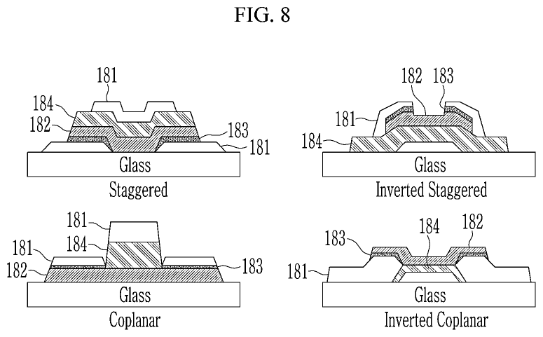

FIG. 8 is a diagram illustrating various TFT structures.

The TFTs of the present disclosure may be implemented in one of the various structures shown in FIG. 8, but the present disclosure is not limited thereto.

As shown in FIG. 8, the TFT structure may be one of a staggered type, an inverted staggered type, a coplanar type, and an inverted coplanar type, depending on the positioning of the gate terminals.

The TFT may include an electrode 181, a semiconductor 182, an ohmic layer 183, and an insulator 184 located on a glass substrate.

Although an exemplary embodiment of the present disclosure has been described in detail, the scope of the present disclosure is not limited by the exemplary embodiment. Various changes and modifications using the basic concept of the present disclosure defined in the accompanying claims by those skilled in the art shall be construed to belong to the scope of the present disclosure.

What is claimed is:

1. A display device comprising:
a first TFT implemented as a Low-Temperature Polycrystalline Silicon (LTPS) TFT;
a second TFT implemented as an oxide TFT stacked on the LTPS TFT; and
a light emitting device formed next to a structure in which the first TFT and the second TFT are stacked,
wherein one electrode of the first TFT is connected to a gate of the second TFT, and one electrode of the second TFT is connected to the light emitting device.

2. The display device of claim 1, wherein:
the second TFT includes:
a first active layer formed on a substrate;
a first insulation layer formed on the first active layer;
a first gate electrode formed on the first insulation layer;
a second insulation layer formed on the first insulation layer and the first gate electrode;
a first electrode layer connected to any one of a source region and a drain region of the first active layer through a first via electrode formed to penetrate the first insulation layer and the second insulation layer and formed on the second insulation layer; and
a second electrode layer connected to the other of the source region and the drain region of the first active layer through a second via electrode formed to penetrate the first insulation layer and the second insulation layer and formed on the second insulation layer, and
the first electrode layer is electrically connected to the light emitting device.

3. The display device of claim 2, wherein:
the first TFT includes:
a third insulation layer formed on the first electrode layer and the second electrode layer;
a second active layer formed on the third insulation layer;
a third electrode layer formed on any one of a source region and a drain region of the second active layer;
a fourth electrode layer formed on the other of the source region and the drain region of the second active layer;
a fourth insulation layer formed on the third insulation layer, the third electrode layer, and the fourth electrode layer; and
a second gate electrode formed on the fourth insulation layer to overlap the second active layer in a vertical direction, and
the third electrode layer is electrically connected to the first gate electrode.

4. The display device of claim 3, further comprising:
a fifth electrode layer connected to the first gate electrode through the first via electrode penetrating the second insulation layer and formed on the third insulation layer,
wherein the third electrode layer is connected to the fifth electrode layer through a via electrode penetrating the third insulation layer.

5. The display device of claim 3, further comprising:
a fifth insulation layer formed on the fourth insulation layer and the second gate electrode; and
a sixth electrode layer and a seventh electrode layer formed on the fourth insulation layer,
wherein the light emitting device includes
an anode connected to the sixth electrode layer and a cathode connected to the seventh electrode layer.

6. The display device of claim 5, wherein:
the seventh electrode layer is connected to the first electrode layer through a via electrode penetrating the third to fifth insulation layers.

7. The display device of claim 1, wherein:
the light emitting device is a micro LED.

8. A method of manufacturing a display device, the method comprising:
forming a first TFT, which is an LTPS TFT, on a substrate;
forming a second TFT, which is an Oxide TFT, on the first TFT; and
forming a light emitting device next to a structure in which the first TFT and the second TFT are stacked,
wherein one electrode of the second TFT is connected to a gate of the first TFT, and one electrode of the first TFT is connected to the light emitting device.
